(19) United States
(12) Patent Application Publication
(10) Pub. No.: US 2007/0020780 A1
(43) Pub. Date: Jan. 25, 2007

(54) Method of processing semiconductor substrate responsive to a state of chamber contamination

(76) Inventors: Kye-Hyun Baek, Gyeonggi-do (KR); Chang-Jin Kang, Gyeonggi-do (KR); Gyung-Jin Min, Seoul (KR); Yong-Jin Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/370,478

(22) Filed: Mar. 7, 2006

(30) Foreign Application Priority Data
Jul. 11, 2005 (KR) 2005-62207

(51) Int. Cl. H01L 21/66; G01R 31/26

(52) U.S. Cl. 438/14

(57) ABSTRACT

In one embodiment, a method of processing a semiconductor substrate includes measuring a state of a processing chamber contamination before processing each semiconductor substrate. A process condition is then changed responsive to the state of chamber contamination to compensate for an influence of the state of chamber contamination on the process condition. If the change in process condition is outside of predetermined margin, a warning may be generated and the process may be stopped.

### CROSS-REFERENCE TO RELATED PATENT APPLICATION

This application claims the benefit of Korean Patent Application No. 10-2005-0062207, filed on Jul. 11, 2005, in the Korean Intellectual Property Office, the disclosure of which is incorporated herein in its entirety by reference.

### BACKGROUND

1. Field of the Invention

The present disclosure relates to a method of fabricating a semiconductor device, and more particularly, to controlling a processing of a semiconductor substrate inside a chamber responsive to a state of chamber contamination.

2. Description of the Related Art

Semiconductor fabrication equipment systems, such as etch equipment for etching a semiconductor substrate, may include at least one chamber having an inner space where the semiconductor substrate is processed. The wall of the chamber may be composed of a ceramic such as anode treated aluminum. However, an etchant used to etch a semiconductor substrate or a material layer, such as Br or Cl for etching silicon, recombines with the anode treated aluminum. Thus, etch processing results may significantly vary depending on the changing condition of the chamber wall.

For example, articles disclosed in J. Vac. Sci. Technol., A16, 270 (1998) and J. Vac. Sci. Technol., A17, 282 (1999) by G. P. Kota, et al. show recombination characteristics of Cl and Br on various surfaces. Referring to FIGS. 1 and 2, it is acknowledged that an oxide-coated chamber (▴) has higher densities of Br and Cl than those of a clean chamber (▪) and a polymer-coated chamber (●).

Thus, it is necessary to clean a chamber every time when each semiconductor substrate is processed in order to maintain uniform etch conditions for each subsequent substrate. For example, pre-cleaning before etching a wafer may be performed or post-cleaning after etching a wafer may be performed. The cleaning may be called in-situ chamber cleaning (ICC) or waferless auto cleaning (WAC).

However, the chamber may not be cleaned completely and the effects of the cleaning are reduced as the number of the wafers processed inside a chamber increases, and thus, RF time of the chamber increases. Referring to FIG. 3, even though the cleaning has been performed, plasma characteristics, such as an electron collision rate, change in accordance with the number of the wafers processed.

For example, an etch depth of a sample wafer in the wafers placed in a same disposition is 5000 Å, but an etch depth of a last wafer changes to 4865 Å. Further, in the case that a process performed in the chamber is changed, for example, as an A process is changed to a B process, and the B process is changed back to the A process, an electron collision rate may be changed.

That is, even though the chamber is cleaned during an etch process for each wafer, a state of the chamber contamination may change in accordance with RF time. Thus, an etch depth of a wafer varies, and as a result, reliability of semiconductor devices decreases.

### SUMMARY

A method of processing a semiconductor substrate includes analyzing by-products that are attached to a semiconductor substrate processing chamber, prior to processing a substrate in the chamber, to measure a state of chamber contamination. A process condition is then changed responsive to the analyzed state of chamber contamination to compensate for an influence of the state of chamber contamination on the process. The semiconductor substrate is then processed using the changed process condition.

The process may be an etching of the semiconductor substrate and measuring the state of chamber contamination may include measuring a density of at least one gas which may an etchant used in etching the semiconductor substrate. Changing a process condition may include changing a density of an etchant used in etching the substrate and may include controlling a plasma ignition power during the etching.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are graphs illustrating changes of densities of Br atoms and Cl atoms in plasma in accordance with a state of a chamber wall respectively;

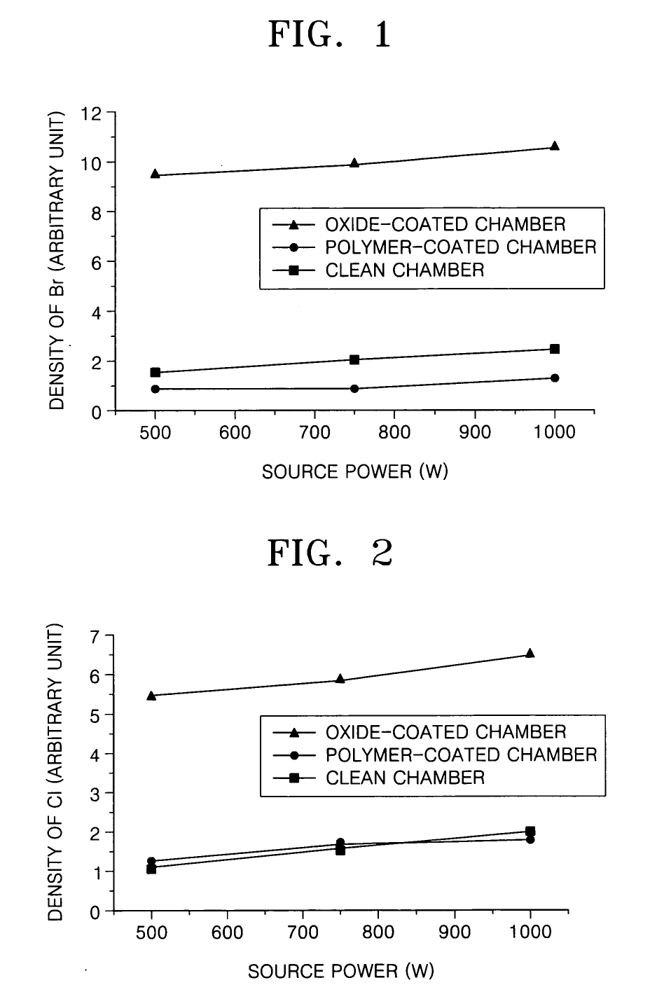

FIG. 3 is a graph illustrating a change of plasma characteristics (electron collision rate) in accordance with a change of a process performed inside a chamber;

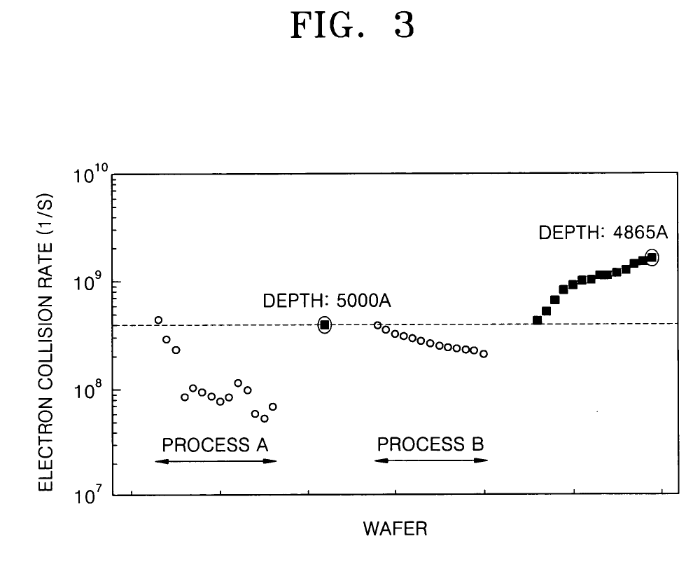

FIG. 4 is a sequence diagram illustrating a method of processing a semiconductor substrate;

FIGS. 5 and 6 are graphs illustrating changes of densities of Cl atoms in accordance with a contaminated state of a chamber during plasma cleaning and semiconductor substrate processing respectively; and

FIG. 7 is a graph illustrating a density of Cl atoms inside plasma in a chamber in accordance with a source power as one of plasma parameters.

### DETAILED DESCRIPTION

The present disclosure will now be described more fully hereinafter with reference to the accompanying drawings, in which preferred embodiments are shown. This disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Like numbers refer to like elements throughout the specification.

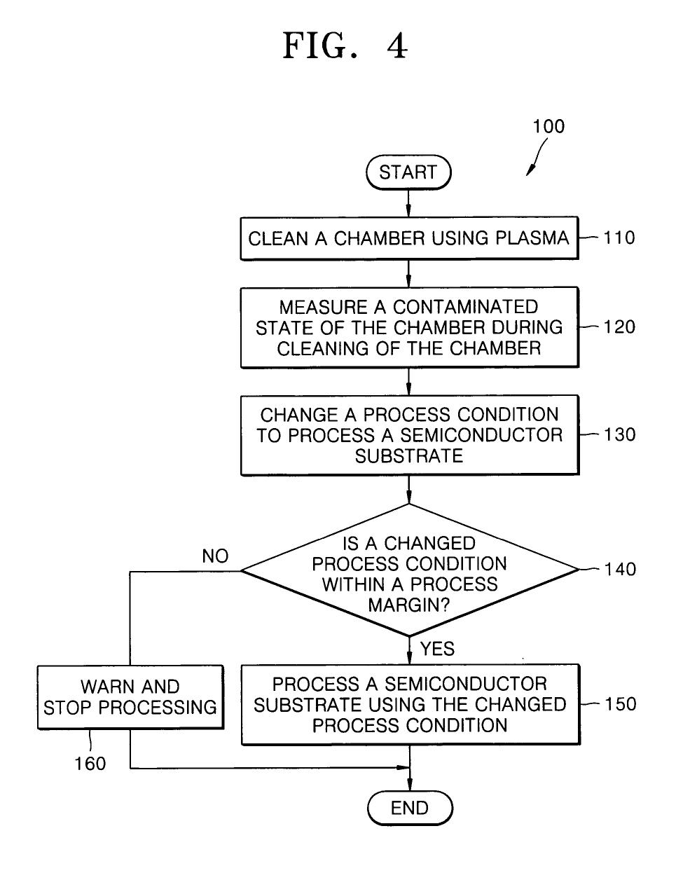

FIG. 4 is a sequence diagram illustrating a method of processing a semiconductor substrate 100. The method of processing a semiconductor substrate 100 may be, for example, a deposition of a material layer on a semiconductor substrate, or etching of the semiconductor substrate or a material layer on the semiconductor substrate. For example, the semiconductor substrate may be a wafer of silicon, silicon-germanium, or silicon on insulator (SOI).

Referring to FIG. 4, a chamber is cleaned using plasma in order to remove contaminants attached to the chamber (step 110). The chamber is confined to its inner space where the semiconductor substrate is processed. Semiconductor fabrication equipment systems may have one chamber or more. The chamber may be structured as one body, or may be composed of a body of a sidewall and a dome covering the body. The structure of the chamber does not limit the scope of the present disclosure, and may be a typical one which is well known to those skilled in this art.

The cleaning may include a pre-cleaning performed before the semiconductor substrate is processed, or a post-cleaning performed after the semiconductor substrate is processed. The cleaning is not confined to what it is called, and may be called ICC, WAC, or the like. The cleaning is performed to remove the contaminants attached to the semiconductor substrate. For example, in the case of a chamber performing an etch process, by-products such as polymer may be attached to the wall of the chamber whenever the etch process is performed on the semiconductor substrate. In the case of silicon etching using Cl or Br etchant, by-products such as CₓF_{y}, SiBrₓO_{y}, SiClₓ, or SiO_{y} may be generated.

The cleaning may use RF plasma. For example, the contaminant attached to the chamber may be physically removed using inert gas plasma such as argon or nitrogen. As another example, the contaminant attached to the chamber may be removed by generating volatile chemicals using plasma of a reactant gas. Alternatively, the inert gas plasma and the reactant gas plasma both may be used concurrently.

During the cleaning of the chamber, a state of chamber contamination is examined (step 120). For example, the state of chamber contamination may be shown as by-products that are generated on the wall of the chamber. Further, according to the article by S. Xu, et al., disclosed in J. Vac. Sci. Technol., A20, 2123 (2002), it is reported that a density of the etchant inside plasma may be changed in accordance with a deposition extent of by-products on the wall of the chamber.

Thus, if a density of at least one gas inside the plasma during the cleaning process (step 110) is measured, an amount of the by-product formed on the wall of the chamber, for example, polymer may be presented as a quantitative term. For example, the gas may include an etchant for etching silicon, that is, Cl or Br. As described above, Cl or Br may be included inside the polymer.

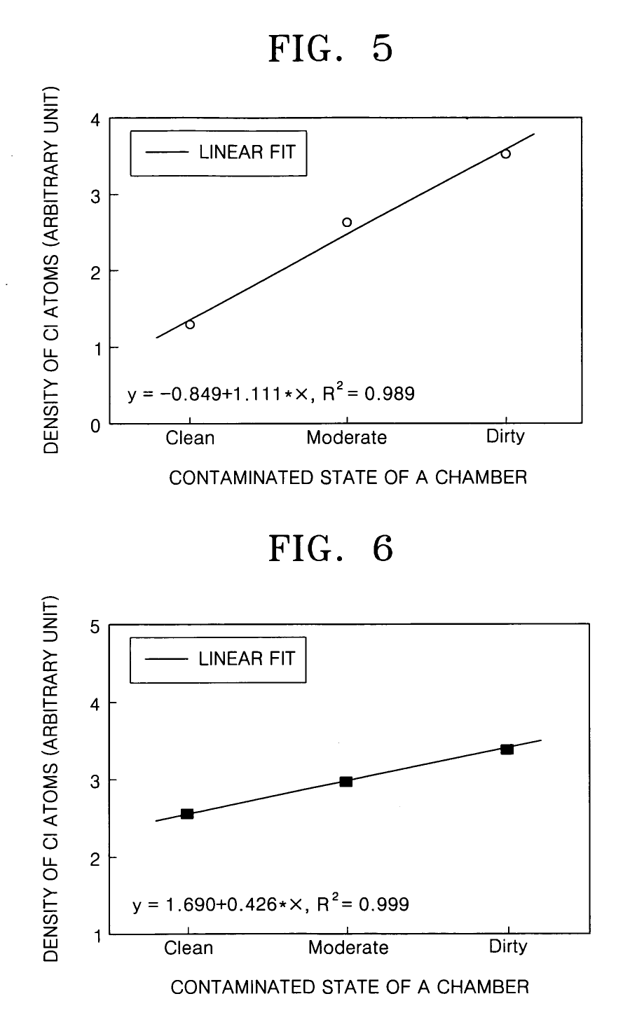

A quantitative analysis for a density of the etchant inside the plasma may be performed using an optical emission spectroscopy (OES) and an argon actinometry. The quantitative analysis may be referred to the article by J. W. Coburn, et al. disclosed in J. Vac. Sci. Technol., 18, 353 (1981). For example, FIGS. 5 and 6 show changes of densities of Cl atoms in accordance with a state of chamber contamination in the cleaning step and the semiconductor substrate processing step respectively.

Referring to FIG. 5, a density of the Cl atoms inside the plasma during the cleaning process (step 110) increases as an extent that the chamber is contaminated increases. That is, as the chamber is changed from a clean state, through a moderate state, to a dirty state, the density of the Cl atoms linearly increases. Thus, if the density of the etchant inside the plasma, for example, Cl or Br during the cleaning process (step 110) is measured, the state of chamber contamination may be predicted.

Then, process conditions for processing the semiconductor substrate may be changed (step 130). The change of the process conditions may be made from feedback information on the state of chamber contamination. Referring to FIG. 6, it is acknowledged that the contaminated state of the chamber has a linear relationship with the density of the Cl atoms during the etch process on the semiconductor substrate. That is, the Cl atoms are short during the etch process in the case that the chamber is clean, but the Cl atoms are excessive during the etch process in the case that the chamber is dirty based on that the chamber is in a moderately contaminated state.

Referring to FIGS. 5 and 6, the process conditions may be changed such that the density of the Cl atoms must be increased during the etch process in the case when the chamber is clean in the cleaning process (step 110), and the density of the Cl atoms must be decreased during the etch process in the case when the chamber is dirty. The change of the density of the etchant Cl is exemplary, and a density of other etchant, for example, Br, may also be changed.

The change of the density of the etchant Cl atoms, as a process condition may be achieved by varying a flow rate of the Cl induced into the chamber. As another example, a plasma ignition may be changed in order to change the density of the Cl atoms inside the plasma during the etch process on the semiconductor substrate.

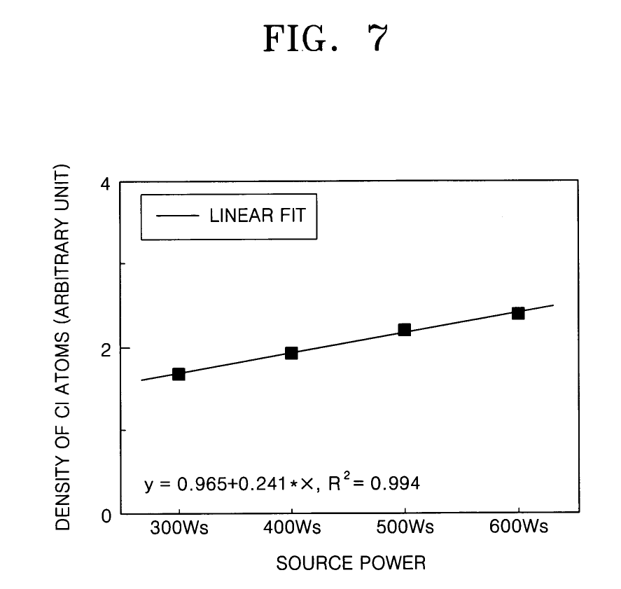

Alternatively, referring to FIG. 7, the density of the Cl atoms inside the plasma during the etch process may also be changed by controlling a source power. That is, the density of the Cl atoms inside the plasma can be increased by increasing the source power. The changes of the process conditions described above are exemplary, but it is also possible to change other parameters to change a density of the etchant inside the plasma.

For example, since the density of the Cl atoms is low (see FIG. 6) when the chamber is clean during the cleaning process (step 110), a process condition may be changed to increase the source power during an etch process. On the contrary, since the density of the Cl atoms is high when the chamber is dirty during the cleaning process (step 110), a process condition may be changed to decrease the source power during an etch process. Thus, the change of the process conditions may be made in response to the feedback information on the state of chamber contamination.

Then, whether the changed process condition is within a process margin or not is checked (step 140). It is intended for the processing to stop when the process condition changes significantly. For example, the process margin may be within a normal process condition of ±15%.

In the case that the changed process margin is not within a desired margin, a warning message is shown to an operator and the processing is stopped by an interlock (step 160). In this case, the chamber may be physically cleaned after checking the state of the chamber. Thus, since a period for the physical cleaning can be predicted, efficiency of equipment system operating is increased. Further, an undesired operating problem is prevented, as in case when processing continues even when the chamber is significantly contaminated. Thus, production yield of products is improved.

However, if the change in process condition is within a desired margin, the semiconductor substrate process continues (step 150). Thus, the semiconductor substrate may be processed continuously and uniformly regardless of the state of chamber contamination. For example, an etch depth of a semiconductor substrate may be uniformly maintained throughout the etching of the substrate regardless of the state of chamber contamination. Therefore, the reliability of semiconductor fabrication processes is increased, and production yield of semiconductor devices is improved.

The description for specific embodiments of the present disclosure as above has been exemplarily provided for the purpose of explanation. For example, as well as the etch process, the present disclosure may also be employed in a deposition process. That is, a deposition condition can be changed in accordance with a state of chamber contamination.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A method of processing a semiconductor substrate comprising:
analyzing by-products attached to a semiconductor substrate processing chamber, before processing a semiconductor substrate in the chamber, to measure a state of chamber contamination;
changing a process condition responsive to the analyzed state of chamber contamination to compensate for an influence of the state of chamber contamination on the process; and
processing the semiconductor substrate in the chamber using the changed process condition.

2. The method of claim 1, wherein analyzing by-products attached to the semiconductor substrate processing chamber includes analyzing a density of at least one gas inside a plasma during cleaning of the chamber using the plasma.

3. The method of claim 2, wherein analyzing a density of at least one gas includes using an optical emission spectroscopy (OES) and an argon actinometry.

4. The method of claim 2, wherein processing the semiconductor substrate includes etching the semiconductor substrate, and analyzing a density of at least one gas includes analyzing an etchant used to etch the semiconductor substrate.

5. The method of claim 4, wherein the etchant includes Cl or Br.

6. The method of claim 1, wherein processing the semiconductor substrate includes etching the semiconductor substrate, and changing a process condition includes changing a density of an etchant used to etch the semiconductor substrate.

7. The method of claim 6, wherein changing a density of an etchant includes controlling a plasma ignition power during the etching.

8. The method of claim 6, wherein changing a density of an etchant includes changing a flow rate of the etchant induced into the chamber during etching.

9. The method of claim 1, further comprising, after changing the process condition, checking whether the changed process condition is within a process margin; and
generating a warning and stopping the processing if the changed process condition is not within the process margin.

10. A method of processing a semiconductor substrate comprising:
cleaning a semiconductor substrate processing chamber using a plasma before processing a semiconductor substrate;
analyzing a density of at least one gas inside the plasma related to a state of chamber contamination during cleaning of the chamber;
changing a process condition responsive to the state of chamber contamination to compensate for an influence of the state of chamber contamination on the process;
checking whether the changed process condition is within a process margin; and
processing the semiconductor substrate in the chamber using the changed process condition if the changed process condition is within the process margin.

11. The method of claim 10, wherein analyzing a density of at least one gas inside the plasma includes using an optical emission spectroscopy (OES) and an argon actinometry.

12. The method of claim 10, further comprising generating a warning if the changed process condition is not within the process margin; and
stopping the processing if the changed process condition is not within the process margin.

13. The method of claim 10, wherein processing the semiconductor substrate includes etching the semiconductor substrate, and
analyzing a density of at least one gas includes analyzing an etchant used to etch the semiconductor substrate.

14. The method of claim 13, wherein changing of the process condition includes controlling a plasma ignition power during the etching.

15. A method of etching a semiconductor substrate using at least one etchant comprising:
cleaning a chamber adapted to perform the etching by using a plasma;
analyzing a density of the etchant inside the plasma during cleaning;
changing a process condition responsive to the density of the etchant inside the plasma; and
etching the semiconductor substrate using the changed process condition.

16. The method of claim 15, wherein analyzing a density of the etchant inside the plasma includes using an optical emission spectroscopy (OES) and an argon actinometry.

17. The method of claim 16, wherein changing a process condition includes controlling a plasma ignition power during the etching.

18. The method of claim 15, further comprising:
after changing the process condition, checking whether the changed process condition is within a process margin or not; and
generating a warning and stopping the etching if the changed process condition is not within the process margin.
